(19) United States
(12) Patent Application Publication
(10) Pub. No.: US 2017/0082842 A1
(43) Pub. Date: Mar. 23, 2017

(54) ULTRA-SMALL CAVITY WITH REFLECTING METASURFACES

(71) Applicants: Amr Mohammad E. A. SHALTOUT, (US); Alexander V. KILDISHEV, West Lafayette, IN (US); Vladimir M. SHALAEV, West Lafayette, IN (US)

(72) Inventors: Amr Mohammad E. A. SHALTOUT, West Lafayette, IN (US); Alexander V. KILDISHEV, West Lafayette, IN (US); Vladimir M. SHALAEV, West Lafayette, IN (US)

(21) Appl. No.: 14/610,931

(22) Filed: Jan. 30, 2015

Related U.S. Application Data
(60) Provisional application No. 61/933,342, filed on Jan. 30, 2014.

(51) Int. Cl. G02B 17/00; H01S 5/10; H01S 5/06; G02B 5/00

(52) U.S. Cl. CPC G02B 17/004; G02B 5/008; H01S 5/1042; H01S 5/0607

(57) ABSTRACT

The present invention provides a new approach for subwavelength cavity solutions. Employment of a reflecting metasurface based on plasmonic nanostructure elements changes the cavity resonance condition that currently causes restrictions on minimum length. The short length of wave propagation between the cavity walls is compensated by strong localization of electromechanical energy near the metasurface walls, which experience considerable phase shifts over a very small distance. Subwavelength 2D and 3D cavities find implementation as laser sources, optical parametric oscillators, interferometers, laser phase and frequency stabilizers, laser spatial and temporal filters, adaptive beam, and pulse shaping devices.

### CROSS-REFERENCE TO RELATED APPLICATIONS

This patent application claims priority to U.S. provisional application No. 61/933,342 filed on Jan. 30, 2014, which fully incorporated herein by reference.

### STATEMENT REGARDING FEDERALLY SPONSORED RESEARCH AND DEVELOPMENT AND GOVERNMENT RIGHTS

This invention was made with government support under FA9550-12-1-0024 awarded by United States Air Force. The government has certain rights in the invention.

### FIELD OF THE INVENTION

The claimed invention of ultra-small cavity via placing phase-fitting metasurfaces coupled to cavity mirrors, relates to the field of nanophotonics, impacting areas including, but not limited to, nanolasers, threshold-less lasing, applications resulting from the Purcell effect, e.g., spontaneous emission enhancement, single photon sources, quantum computation devices, and nanometer scale cavity-based optical devices such as optical parametric oscillators, interferometers, laser phase and frequency stabilizers, laser spatial and temporal filters, adaptive beam, and pulse shaping devices.

### BACKGROUND OF THE INVENTION

Light confinement in conventional cavities like Fabry-Perot, made of parallel mirrors, should satisfy a resonant condition of having a round trip phase shift of an integer multiple of 2 π. This implies that the cavity should have a length equal to an integer number of half the wavelength, setting a lower limit to the length of the cavity of λ/2 and a minimum modal volume of λ³/8.

Minimizing the cavity size below the aforementioned limit has numerous applications including nano-lasers, and a set of applications coming from the Purcell effect of enhancement of spontaneous emission rate which is inversely proportional to the volume of the cavity. This effect is useful in single photon sources, quantum computation devices, and in threshold-less lasing. Additionally, it is aimed to scale down the size of optical components to be compatible with the size of nano-electronic devices, and there are numerous cavity-based optical device applications including, but not limited to, optical parametric oscillators, interferometers, laser phase and frequency stabilizers, and laser spatial and temporal filters.

Different techniques have been proposed to scale-down the size of cavities including using metamaterials with negative permittivity and permeability, photonic crystal cavities, cavities confining surface plasmon waves, and cavities having meta-film layers in the middle of the cavity between two dielectric layers. The technique of using negative permittivity and permeability is complicated in practice, e.g., to build a bulk meta-material with such properties, and it would include losses due to a large amount of metal used in the meta-material. Photonic crystal cavities can provide very high Quality factors (Q), but their size is limited by the wavelength order and they do not reach deep sub-wavelength. Cavities operating on surface plasmon polariton (SPP) waves can reach very small sizes, but SPP waves have resonant modes that are dissimilar to modes existing in conventional optic devices, making it harder to couple waves to and from SPP cavities, or to integrate them efficiently with external devices. Solutions provided using meta-films embedded between dielectric layers have limited effects of reducing the size of the cavity by a factor of only 2 or 3. This limited effect is due to the relatively week coupling of a wave to one layer of metafilm (compare with the strong coupling of a wave to a metasurface coupled to mirrors with the strong physical effect of gap plasmon resonance).

Using a parallel plate cavity to replace the conventional mirrors introduces a phase shift of π for each mirror with a reflecting metasurface that introduces an arbitrary phase shift to the reflected wave, which will change the roundtrip phase condition, and the length of the cavity will no longer keep the lower bound of λ/2.

It is important that the surface replacing the mirror does not change the phase shift at the expense of light confinement inside the cavity. For example, using metals with high losses as mirrors can result in a reflecting phase shift different from IC due to a significant portion of the wave penetrating through the metal during reflection. Such a structure can have a distance between mirrors of less than λ/2 but the mode will not truly be confined between minors, as part of the mode will penetrate the metal, causing high losses and a very unreliable quality factor.

### SUMMARY OF THE INVENTION

The present invention provides a new approach for subwavelength cavity solutions.

Employment of a reflecting metasurface based on plasmonic nanostructure elements changes the cavity resonance condition that currently causes restrictions on minimum length. This also does not occur at the expense of light confinement inside the cavity because plasmon elements couple electromagnetic waves into free electron plasma. Hence, the localized energy not only exists in the form of electromagnetic energy but also exists in the form of mechanical energy of oscillating electrons over very short-length scales near the metasurface. Physically speaking, the short length of wave propagation between the cavity walls is compensated by strong localization of electromechanical energy near the metasurface walls, which experience considerable phase shifts over a very small distance. All energy forms remain highly confined between the cavity walls.

### BRIEF DESCRIPTION OF DRAWINGS

FIG. 1 illustrates the general design behind the present invention. FIG. 1(a) shows the prior art, while FIG. 1(b) shows the present invention.

FIG. 2 shows an example of (a) a cross-sectional view of the present invention, and (b) a top view of the present invention.

FIG. 3 shows, in cross-sectional view, another example of the present invention which involves adding a top layer of metal over extra-deposited dielectric polymer.

FIG. 4 shows a 3D view of the example in FIG. 3.

FIG. 5 shows how metasurfaces can be used on both sides of a cavity employing graphene disks.

FIG. 6 shows an example of a cavity implementing curved mirrors and surfaces.

FIG. 7 shows an example of an FEM simulation result of exciting a cavity designed for the present invention.

FIG. 8 shows how the present invention can be tuned and/or adjusted for various applications in the field.

FIG. 9 shows a cascading cavity array example.

FIG. 10 shows a parallel cavity array example.

FIG. 11 shows another example of a configuration for the present invention.

### DESCRIPTION OF THE INVENTION

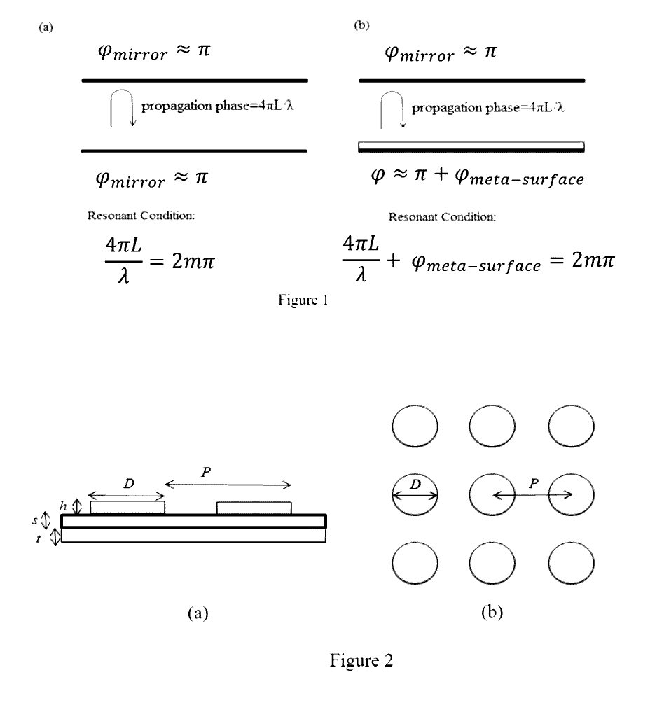

The abstract design of the invention is illustrated by FIG. 1, which shows a comparison between a conventional parallel mirror Fabry-Pérot resonator (FIG. 1(a)) and the currently disclosed structure, where one or both mirrors are coupled to a metasurface (FIG. 1(b)), adding an arbitrary phase shift of φ_{meta-surface}. In the conventional case, the resonance condition is 4πL/λ=2mλ, imposing a minimum limit of λ/2 on the value of L. With the present invention structure, however, the resonance condition becomes 4πL/λ+φ_{meta-surface}=2mπ. With the fact that φ_{meta-surface} can be designed to take on any value from 0 to 2 π, the effect is no constraint on L, allowing L to be arbitrarily small. Although fabrication techniques might currently place constraints on size, there are no fundamental physical size constraints on the present invention. The fabrication and use of smaller-scale devices such as those described herein are more useful and more applicable because they are highly integrable, more suitable for on-chip applications, size compatible with nano-electronic components, and can form the building block of important cavity based applications like nano-lasers. Besides, this small size enhances interesting physical effects like the rate of spontaneous emission of photons, known as Purcell effect which is very useful in quantum electrodynamic applications such as single photon sources. 1000221 One of the techniques that can introduce any phase shift from 0 to 2 π in reflection is the use of gap plasmon metasurfaces. Gap plasmon structure is obtained by having a dielectric positioned between two metal layers. FIG. 2 shows the section view (a) and the top view (b) of a proposed structure of a gap plasmon metasurface consisting of a bottom reflecting metal layer that can be made of any metal, e.g., gold, silver, titanium nitride, having a thickness, t, which is on the order of 20-30 nm, and an upward array of metal disks of diameter D, periodicity P, and thickness h. In between, there exists a dielectric spacer layer of thickness s which can be alumina, silica, or another dielectric. Thicknesses h and s typically range in the range of tens of nanometers. Periodicity P and diameter D ranges depend on the wavelength of operation. For example, working in the visible range would make typical values of P range from 100-300 nm, and values of D ranging from about 30% to 70% of the value of P.

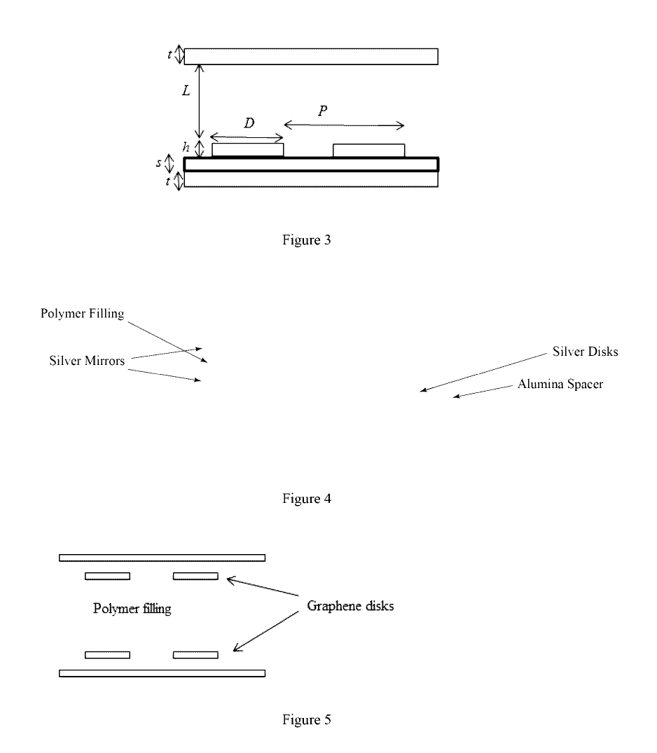

Adding top layer of metal over extra-deposited dielectric polymer will result in a cavity structure. The cross-section of such a structure is shown in FIG. 3, while a 3D view is shown in FIG. 4.

In the preferred embodiment the multilayer structure of FIG. 3 is built on top of dielectric substrate (glass, polymer, silicon, . . . etc) in the following steps: (1) a thin metal layer is deposited on top of substrate using PVD (physical vapor deposition); (2) then on top of it, a spacer layer is deposited using ALD (atomic layer deposition); (3) metallic discs are then deposited using EBL (electron beam lithography); (4) a polymer filling is then added using spin coating; and then (5) the top metal layer is deposited using PVD. Similar procedure was used to build the parallel cavity structure of FIG. 10.

It is possible also to use a metasurface with both mirrors, applicable to cases such as the use of graphene disks. Graphene has a remarkable feature of having a plasmonic resonance in the infrared region (6-7 μm wavelength) using very thin disks with a thickness on the order of 1 nm, but the phase shift obtained from this resonance doesn't span the entire range from 0 to 2 π. Using metasurfaces with both mirrors, as shown in FIG. 5, expands the span of the phase shift.

The structures currently disclosed are easily implemented using well-established fabrication techniques. Metal thin films and alumina spacers are obtained using Physical Vapor Deposition (PVD). Spacers can be also fabricated using Atomic Layer Deposition (ALD). Spin coating or PVD can be used to produce the polymer filling. Electron Beam Lithography (EBL) is used to compose the array of metallic disks. For the case of ciraphene array, Chemical Vapor Deposition (CVD) is used. Standard nanofabrication techniques and conditions are used.

For the graphene structure FIG. 5, the fabrication steps are modified as follows: (1) a thin metal layer is deposited on top of substrate using PVD; (2) then on top of it, a spacer layer is deposited using ALD; (3) graphene discs are then deposited using CVD; (3) a polymer filling is then added using spin coating; (4) a second layer of graphene discs is then deposited using CVD; (5) a second spacer layer is deposited using ALD; (6) then the top metal layer is deposited using PVD.

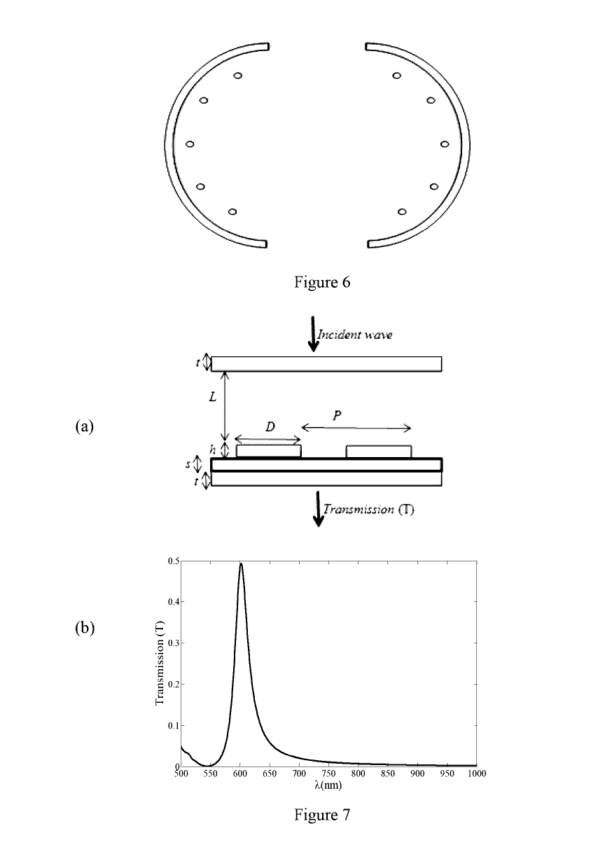

In another embodiment, the structure can be implemented with curved mirrors, e.g., spherical or parabolic mirrors, as shown in FIG. 6. Such structure can be useful instead of flat mirrors to accommodate working with Gaussian beams, or it can be used to implement resonator types other than plane-parallel, such as the confocal, spherical, and hemispherical types. 1000291 For curved structure of FIGS. 6 and 2D structures in FIG. 11, an alternative fabrication approach is used, where the same dielectric material is used for the spacer and cavity filling. We use a substrate of the dielectric (polymer, Si, alumina, . . . etc), and perform etching to make a structure of holes with the cross sections similar to the images in FIG. 6 or 11, and then fill these holes with metals using CVD.

FIG. 7 shows (a) a cross-sectional diagram of exciting a cavity and (b) the FEM simulation result of exciting a cavity using an upward incident plane wave and plotting the transmitted power ratio (T) as a function of wavelength. The materials used for simulation are silver for metals, alumina for spacer, and PMMA for the dielectric in the rest of the cavity. Dimensions used are P=100 nm, D=40 nm, L=60 nm, t=25 nm, s=h=20 nm. For the result, the resonance is obtained at λ=601 nm, and the FWHM bandwidth is 28 nm. Thus, the quality factor is Q=601/28=21.5.

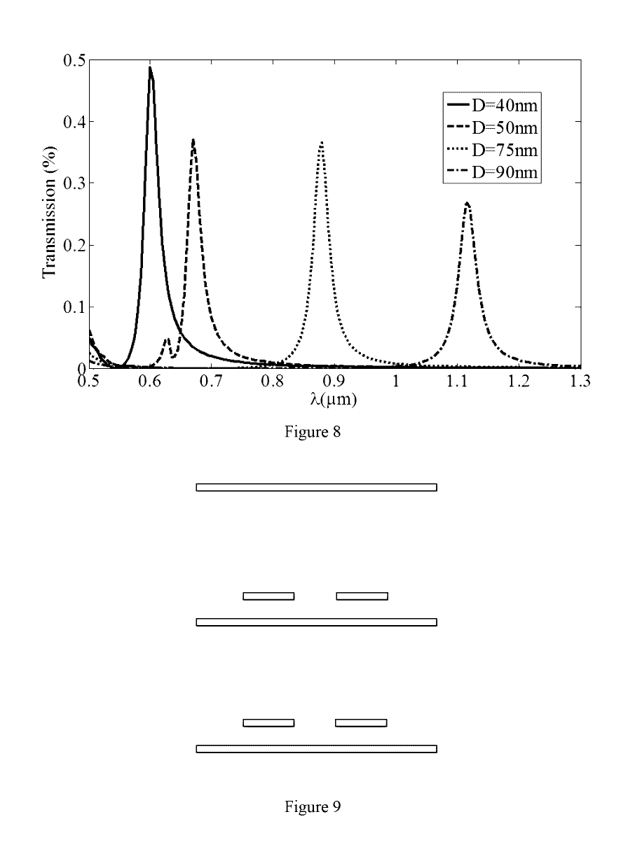

The design can be adjusted during fabrication to obtain resonance at various wavelength ranges. Changing dimensions can tune the resonant wavelength across the visible and near-IR range. Changing materials (e.g., switching from silver to graphene) can move the resonant wavelength to far IR ranges. FIG. 8 shows several simulations, using the same structure as that for FIG. 7 but changing the value of D from 40 nm to 50 nm, 75 nm, and 90 nm, resulting in a gradual change of the resonant wavelength from 0.6 μm to 1.1 μm.

The structure can also be used to make a device that is tunable after fabrication. It can be tuned, for example, using light, bias voltage, or temperature. To tune using a control light source, the metallic disks can be replaced with amorphous silicon. A control light signal can be used to excite electron-hole pairs and the hence change the free carrier concentration. Also these disks can be replaced with highly doped semiconductors where the carrier concentration varies based on the applied voltage. Temperature-based tuning is possible if the spacer or the polymer are replaced with liquid crystal, which varies in refractive index based on temperature.

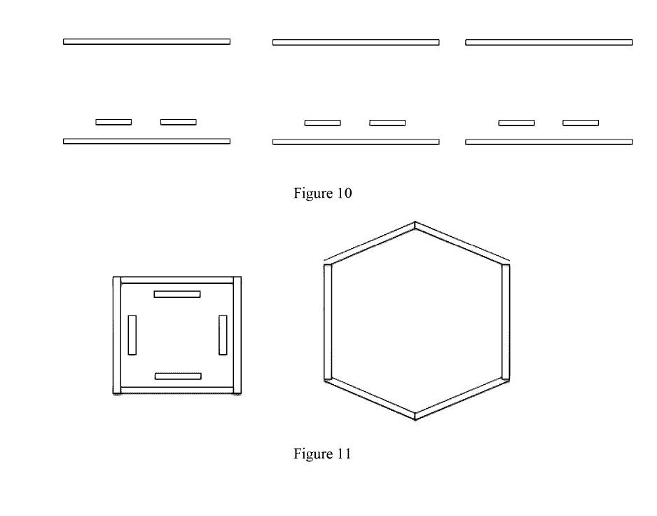

The structure of the present invention can be used to build an array of cascading cavities, as shown in FIG. 9, or an array of parallel cavities, as shown in FIG. 10. Parallel cavities can comprise a 1D or a 2D array. For cascaded cavity of FIG. 9, we use same fabrication steps as described in [00022] and then keep repeating steps 2-5 on top of the structure depending on the number of cavities we need.

Arrays of cavities can be used in many applications including, but not limited to, quantum electrodynamics applications, where single photon emitters are coupled to each other to generate entangled photons, or to generate other forms of entangled qubits, such as entangling 2 level atoms in adjacent cavities. Other applications of cavity arrays include pulse shaping and imaging applications through spatial variation of cavities. They can also be used to obtain compact arrays of laser sources for optical signal processing.

It will be understood by those skilled in the art that various changes in form and details may be made therein without departing from the spirit and scope of the invention as set forth in the appended claims. Those skilled in the art will recognize, or be able to ascertain using no more than routine experimentation, many equivalents to the specific embodiments of the invention described herein. Such equivalents are intended to be encompassed in the scope of the claims.

Moreover, the words “example” or “exemplary” are used herein to mean serving as an example, instance, or illustration. Any aspect or design described herein as “exemplary” is not necessarily to be construed as preferred or advantageous over other aspects or designs. Rather, use of the words “example” or “exemplary” is intended to present concepts in a concrete fashion. As used in this application, the term “or” is intended to mean an inclusive “or” rather than an exclusive “or”. That is, unless specified otherwise, or clear from context, “X employs A or B” is intended to mean any of the natural inclusive permutations. That is, if X employs A; X employs B; or X employs both A and B, then “X employs A or B” is satisfied under any of the foregoing instances. In addition, the articles “a” and “an” as used in this application and the appended claims should generally be construed to mean “one or more” unless specified otherwise or clear from context to be directed to a singular form.

What is claimed is:

1. A subwavelength scale device, comprising:
at least two mirrors with at least one of them being a gap plasmon metasurface mirror, the mirrors facing each other to form a cavity, wherein said cavity exhibit(s) resonance in the range of λ=0.6 μm to λ=1.1 μm, and wherein the distance between said mirrors is about 100 nm.

2. The device according to claim 1, wherein more than one gap plasmon metasurface mirrors combine to form a 2-dimensional cavity structure.

3. The device according to claim 1, wherein more than two gap plasmon metasurface mirrors combine to form a 3-dimensional cavity structure.

4. The device according to claim 1, wherein a cavity structure is rectangular.

5. The device according to claim 1, wherein a cavity structure is hexagonal.

6. The device according to claim 1, wherein a cavity structure is circular.

7. The device according to claim 1, further comprising a tunability function wherein a resonant wavelength changes with a control light.

8. The device according to claim 1, further comprising a tunability function wherein a resonant wavelength changes with a bias voltage.

9. The device according to claim 1, further comprising a tunability function wherein a resonant wavelength changes with a temperature change.

10. The device according to claim 1, further comprising an array of cascading cavities.

11. The device according to claim 1, further comprising an array of parallel cavities.

12. The device of claim 1, wherein the device is used for nanolasers, thresholdless lasing, spontaneous emission enhancement, a single photon source, quantum computation, an optical parametric oscillator, an interferometer, a laser phase or frequency stabilizer, a laser spatial filter, and a laser temporal filter.

13. The device of claim 1, wherein the device is used for optical signal processing, pulse shaping, and imaging.

14. A method of fabricating a subwavelength scale device, said device comprising at least two gap plasmon metasurface minors facing each other at a distance of about 100 nm, said device spanning wavelengths ranging from 0.6 μm to 1.1 μm, the method comprising:
depositing a thin metal on a dielectric substrate,
depositing a spacer layer on said thin metal on said substrate,
depositing one or more metallic discs on said spacer layer on said thin metal on said substrate,
adding a polymer filling to said spacer layer,
and depositing a top metal layer.

15. The method of claim 14, wherein said thin metal is deposited using physical vapor deposition (PVD).

16. The method of claim 14, wherein said spacer layer is deposited using atomic layer deposition (ALD).

17. The method of claim 14, wherein said metallic discs are deposited using electron beam lithography (EBL).

18. The method of claim 14, wherein said polymer filling is added using spin coating.

19. The method of claim 14, wherein said top layer is deposited using PVD.

20. A method of fabricating a subwavelength scale device, said device comprising an array of cascading cavities, each cavity comprising at least two gap plasmon metasurface mirrors facing each other at a distance of about 100 nm, said device spanning wavelengths ranging from 0.6 μm to 1.1 μm, the method comprising:
depositing a thin metal on a dielectric substrate (step 1),
depositing a spacer layer on said thin metal on said substrate (step 2),
depositing one or more metallic discs on said spacer layer on said thin metal on said substrate (step 3),
adding a polymer filling to said spacer layer(step 4),
depositing a top metal layer (step 5),
and repeating said step 2 through step 5 to form a cascading pattern of cavities.
